(19) United States
(12) Patent Application Publication
(10) Pub. No.: US 2026/0074149 A1
(43) Pub. Date: Mar. 12, 2026

(54) PLASMA PROCESSING APPARATUS AND METHOD OF CONTROLLING THE SAME

(71) Applicant: Tokyo Electron Limited, Tokyo (JP)

(72) Inventor: Takeshi KOBAYASHI, Iwate (JP)

(21) Appl. No.: 19/315,725

(22) Filed: Sep. 1, 2025

(30) Foreign Application Priority Data
Sep. 11, 2024 (JP) 2024-157823

(51) Int. Cl. H01J 37/32

(52) U.S. Cl. CPC H01J 37/32183

(57) ABSTRACT

The plasma processing apparatus includes a radio-frequency power supply, a pair of plasma electrodes, a matching box located between the pair of plasma electrodes and the radio-frequency power supply and having an impedance matching circuit including a first variable inductor and a second variable inductor, and a control unit. The control unit executes performing impedance matching by varying the inductance of the first variable inductor and the inductance of the second variable inductor, obtaining the efficiency of the matching box based on the inductance of the first variable inductor and the inductance of the second variable inductor after the impedance matching and the efficiency map, and calculating output power of the radio-frequency power supply based on the obtained efficiency of the matching box and supply power supplied to the plasma electrodes, and controlling the output power of the radio-frequency power supply based on the calculated output power.

### CROSS REFERENCES TO RELATED APPLICATIONS

This application is based on and claims priority from Japanese Patent Application No. 2024-157823, filed on Sep. 11, 2024, with the Japan Patent Office, the disclosure of which is incorporated herein in its entirety by reference.

### TECHNICAL FIELD

The present disclosure relates to a plasma processing apparatus and a method of controlling the plasma processing apparatus.

### BACKGROUND

Japanese Patent Laid-Open Publication No. 2020-092036 discloses a method of controlling a plasma processing apparatus, the apparatus including a radio-frequency power supply that applies radio-frequency power to a substrate holder inside a chamber, a matching box provided between the substrate holder and the radio-frequency power supply, and a plasma generator that generates a plasma from a gas using the radio-frequency power.

### SUMMARY

To address the above object, according to one embodiment, there is provided a plasma processing apparatus including a radio-frequency power supply, a pair of plasma electrodes, a matching box located between the pair of plasma electrodes and the radio-frequency power supply and having an impedance matching circuit including a first variable inductor and a second variable inductor, and a control unit. The control unit has an efficiency map that correlates an inductance of the first variable inductor and an inductance of the second variable inductor with an efficiency of the matching box. The control unit is configured to execute performing impedance matching by varying the inductance of the first variable inductor and the inductance of the second variable inductor, obtaining the efficiency of the matching box based on the inductance of the first variable inductor and the inductance of the second variable inductor after the impedance matching and the efficiency map, and calculating output power of the radio-frequency power supply based on the obtained efficiency of the matching box and supply power supplied to the plasma electrodes, and controlling the output power of the radio-frequency power supply based on the calculated output power.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic diagram illustrating a configuration example of a substrate processing apparatus.

FIG. 2 is a circuit diagram illustrating an example of a circuit that supplies radio-frequency power to a plasma electrode.

FIG. 3 is a schematic diagram illustrating a configuration of a variable inductor.

FIG. 4 is an example of a flowchart illustrating an impedance matching processing.

FIG. 5 is an example of an efficiency map of a matching box.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for carrying out the present disclosure will be described with reference to the drawings. In each drawing, the same reference numerals may be given to the same components, and redundant descriptions may be omitted.

### [Substrate Processing Apparatus]

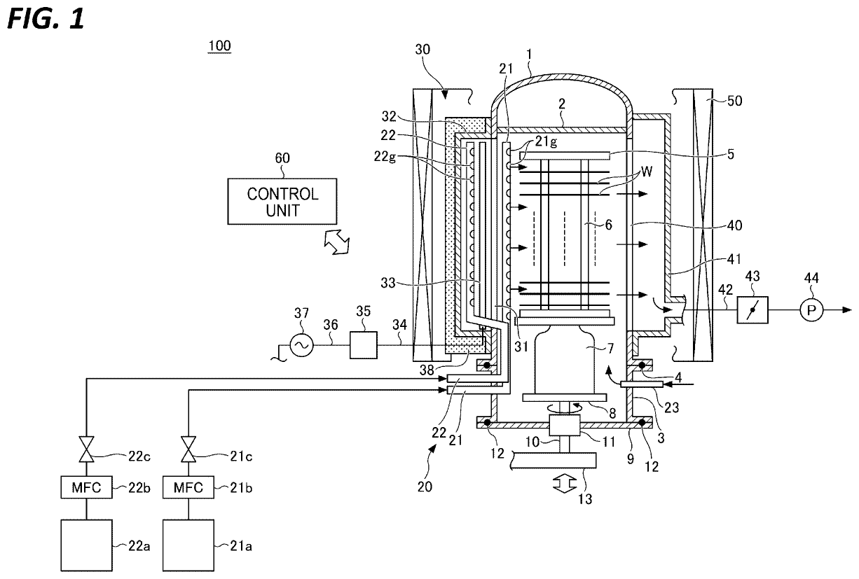

An example of a substrate processing apparatus (e.g., plasma processing apparatus) 100 according to the present embodiment will be described with reference to FIG. 1. FIG. 1 is a schematic diagram illustrating a configuration example of the substrate processing apparatus 100. In the following description, the substrate processing apparatus 100 will be described as an example of a film forming apparatus that forms a silicon nitride film on a substrate W by an atomic layer deposition (ALD) process using, for example, a plasma of a silicon-containing gas and a nitrogen-containing gas.

The substrate processing apparatus 100 includes a ceilinged cylindrical processing container 1 with an open bottom. The entire processing container 1 is made of, for example, quartz. A ceiling plate 2, which is made of quartz. Is provided near the top inside the processing container 1, and the region under the ceiling plate 2 is sealed. A cylindrically-molded metallic manifold 3 is connected to a bottom opening of the processing container 1 via a seal member 4 such as an O-ring.

The manifold 3 supports the bottom of the processing container 1, and a wafer boat 5 (e.g., a substrate holder), on which a plurality (e.g., 25 to 150) of semiconductor wafers (hereinafter referred to as “substrates W”) are stacked in multiple stages, is inserted into the processing container 1 from below the manifold 3. As such, the plurality of substrates W are accommodated substantially horizontally inside the processing container 1 at intervals in the vertical direction. The wafer boat 5 is made of, for example, quartz. The wafer boat 5 includes three rods 6 (two rods are illustrated in FIG. 1), and the plurality of substrates W are supported by grooves (not illustrated) formed in the rods 6.

The wafer boat 5 is disposed on a table 8 via a heat reservoir 7 made of quartz. The table 8 is supported on a rotating shaft 10, which penetrates a metallic (e.g., stainless steel) lid 9 that opens or closes a bottom opening of the manifold 3.

A magnetic fluid seal 11 is provided around a penetrating portion of the rotating shaft 10 to airtightly seal and rotatably support the rotating shaft 10. A seal member 12 is provided between a peripheral portion of the lid 9 and the bottom of the manifold 3 to maintain airtightness inside the processing container 1.

The rotating shaft 10 is attached to the tip of an arm 13, which is supported by an elevating mechanism (not illustrated) such as, for example, a boat elevator. The wafer boat 5 and the lid 9 are integrally moved up and down and are inserted into or removed from the processing container 1. The table 8 may be fixed at the lid 9 side, such that the substrates W are processed without rotating the wafer boat 5.

Further, the substrate processing apparatus 100 includes a gas supply unit 20 (e.g., a processing gas supply) that supplies predetermined gases such as a processing gas and a purge gas into the processing container 1.

The gas supply unit 20 includes gas supply pipes 21, 22 and 23. The gas supply pipe 21 is made of, for example, quartz, and inwardly penetrates the sidewall of the manifold 3 and is bent upward to extend vertically. A plurality of gas holes 21g are formed at predetermined intervals in a vertical portion of the gas supply pipe 21 over a vertical length corresponding to the wafer support range of the wafer boat 5. Each gas hole 21g discharges a gas in the horizontal direction. The gas supply pipe 22 is made of, for example, quartz, and inwardly penetrates the sidewall of the manifold 3 and is bent upward to extend vertically. A plurality of gas holes 22g are formed at a predetermined interval in a vertical portion of the gas supply pipe 22 over a vertical length corresponding to the wafer support range of the wafer boat 5. Each gas hole 22g discharges a gas in the horizontal direction. The gas supply pipe 23 is made of, for example, quartz, and includes a short quartz pipe provided to penetrate the sidewall of the manifold 3.

The vertical portion (e.g., in which the gas holes 21g are formed) of the gas supply pipe 21 is located inside the processing container 1. A processing gas (e.g., precursor gas) is supplied to the gas supply pipe 21 from a gas source 21a through a gas pipe. The gas pipe is provided with a flow rate controller 21b and an on-off valve 21c. Thus, the processing gas from the gas source 21a is supplied into the processing container 1 through the gas pipe and the gas supply pipe 21. The processing gas supplied from the gas source 21a is, for example, a silicon-containing gas. The silicon-containing gas is, for example, dichlorosilane (DCS, SiH₂Cl₂).

The vertical portion (in which the gas holes 22g are formed) of the gas supply pipe 22 is located in a plasma generation space to be described later. A processing gas (e.g., reactant gas or nitriding gas) is supplied to the gas supply pipe 22 from a gas source 22a through a gas pipe. The gas pipe is provided with a flow rate controller 22b and an on-off valve 22c. Thus, the processing gas from the gas source 22a is supplied to the plasma generation space through the gas pipe and the gas supply pipe 21. Then, the processing gas is turned into a plasma in the plasma generation space and is supplied into the processing container 1. The processing gas supplied from the gas source 22a is, for example, a nitrogen-containing gas. The nitrogen-containing gas may be, for example, NH₃.

A purge gas is supplied to the gas supply pipe 23 from a purge gas source (not illustrated) through a gas pipe. The gas pipe (not illustrated) is provided with a flow rate controller (not illustrated) and an on-off valve (not illustrated). Thus, the purge gas from the purge gas source is supplied into the processing container 1 through the gas pipe and the gas supply pipe 23. The purge gas supplied from the purge gas source is, for example, an inert gas such as argon (Ar) or nitrogen (N₂). Further, a case where the purge gas is supplied into the processing container 1 through the gas supply pipe 23 has been described, but the present disclosure is not limited thereto. The purge gas may also be supplied into the processing container 1 through either the gas supply pipe 21 or the gas supply pipe 22.

A plasma generation mechanism 30 is formed on a part of the sidewall of the processing container 1. The plasma generation mechanism 30 forms a plasma from the processing gas from the gas source 22a.

The plasma generation mechanism 30 includes a plasma partition wall 32, a pair of plasma electrodes 33 (e.g., one electrode is illustrated in FIG. 1), a feed line 34, a matching box 35, a coaxial cable 36, a radio-frequency power supply 37, and an electrical-insulation protective cover 38.

The plasma partition wall 32 is airtightly welded to the outer wall of the processing container 1. The plasma partition wall 32 is made of, for example, quartz. The plasma partition wall 32 has a concave cross-sectional shape, and covers an opening 31 formed in the sidewall of the processing container 1. The opening 31 is formed in a vertically elongated shape, so as to cover all of the substrates W supported by the wafer boat 5 in the vertical direction. The gas supply pipe 22 for discharging the processing gas is located in an inner space, which is defined by the plasma partition wall 32 and communicates with the inside of the processing container 1, for example, in the plasma generation space. The gas supply pipe 21 for discharging the processing gas is located at a position close to the substrates W along the inner sidewall of the processing container 1 outside the plasma generation space.

The pair of plasma electrodes 33 (e.g., one electrode is illustrated in FIG. 1) each have an elongated shape, and are vertically arranged on opposite sides of the outer wall surface of the plasma partition wall 32. Each plasma electrode 33 is held, for example, by a holder (not illustrated) provided on the side surface of the plasma partition wall 32. The feed line 34 is connected to the bottom of each plasma electrode 33.

The feed line 34 electrically interconnects each plasma electrode 33 and the matching box 35. In the illustrated example, the feed line 34 has one end connected to the bottom of each plasma electrode 33 and the other end connected to the matching box 35.

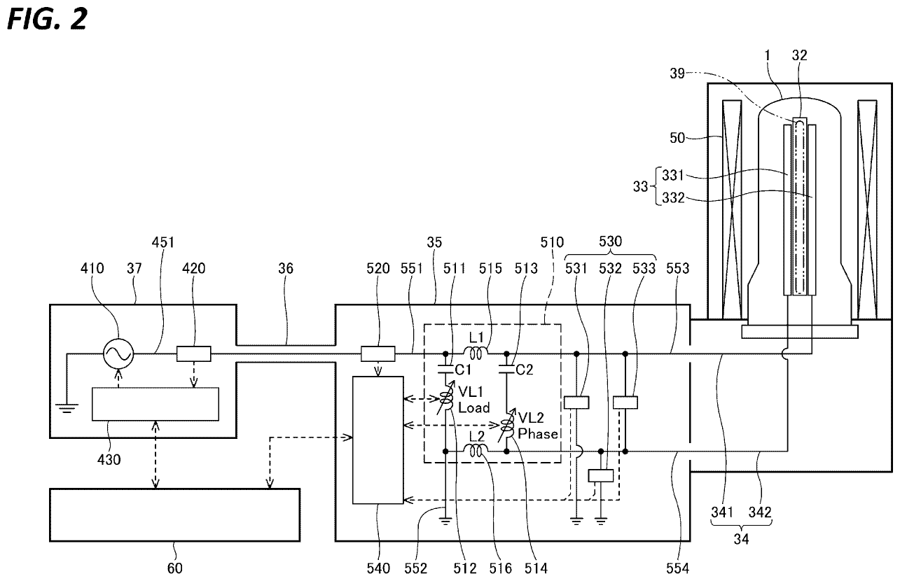

The matching box 35 includes an impedance matching circuit 510 (see, e.g., FIG. 2 to be described later) and performs impedance matching between the radio-frequency power supply 37 and the substrate processing apparatus 100 (the pair of plasma electrodes 33).

The coaxial cable 36 electrically interconnects the matching box 35 and the radio-frequency power supply 37.

The radio-frequency power supply 37 is connected to the bottom of each plasma electrode 33 through the coaxial cable 36, matching box 35, and feed line 34, and supplies radio-frequency power of, for example, 13.56 MHz to the pair of plasma electrodes 33. Thus, the radio-frequency power is applied to the plasma generation space defined by the plasma partition wall 32. The processing gas (nitrogen-containing gas) discharged from the gas supply pipe 22 is turned into a plasma inside the plasma generation space to which the radio-frequency power has been applied, and is then supplied to the inside of the processing container 1 through the opening 31.

The electrical-insulation protective cover 38 is attached to the exterior of the plasma partition wall 32 so as to cover the plasma partition wall 32. A coolant passage (not illustrated) is provided in an inner portion of the electrical-insulation protective cover 38, and the plasma electrodes 33 are cooled by flowing a coolant such as a cooled nitrogen (N₂) gas through the coolant passage. Further, a shield (not illustrated) may be provided between the plasma electrodes 33 and the electrical-insulation protective cover 38 to cover the plasma electrodes 33. The shield is made of, for example, a good conductor such as a metal, and is grounded.

An exhaust port 40 (e.g., an exhaust unit) for evacuating the inside of the processing container 1 is provided on a sidewall portion of the processing container 1 at the opposite side of the opening 31. The exhaust port 40 is formed in a vertically elongated shape to correspond to the wafer boat 5. An exhaust port cover member 41, which is molded into a U-shaped cross-sectional shape, is attached to a portion of the processing container 1 corresponding to the exhaust port 40 so as to cover the exhaust port 40. The exhaust port cover member 41 extends upward along the sidewall of the processing container 1. An exhaust pipe 42 for evacuating the processing container 1 through the exhaust port 40 is connected to a lower portion of the exhaust port cover member 41. The exhaust pipe 42 is connected to both a pressure control valve 43, which is used to control the internal pressure of the processing container 1, and an exhaust device 44, which includes a vacuum pump and others. As such, the inside of the processing container 1 is evacuated by the exhaust device 44 through the exhaust pipe 42.

A cylindrical heating mechanism 50 is provided around the processing container 1. The heating mechanism 50 heats the processing container 1 and the substrates W inside the processing container 1. The heating mechanism 50 controls the temperature of the processing container 1 to a desired temperature. Thus, the substrates W inside the processing container 1 are heated by, for example, radiant heat from the wall surface of the processing container 1.

Further, the substrate processing apparatus 100 includes a control unit 60. The control unit 60 controls, for example, operations of various components of the substrate processing apparatus 100 such as the supply and stoppage of gases by the opening and closing of the on-off valves 21c and 22c, gas flow rate control through the flow rate controllers 21b and 22b, and evacuation control using the exhaust device 44. Further, the control unit 60 controls, for example, the On/Off of radio-frequency power by the radio-frequency power supply 37 and the temperatures of the processing container 1 and the substrates W inside the processing container 1 by the heating mechanism 50. Further, the control unit 60 controls the matching box 35.

The control unit 60 may be, for example, a computer, among others. Further, computer programs for executing operations of various components of the substrate processing apparatus 100 are stored in a storage medium. The storage medium may be, for example, a flexible disk, compact disk, hard disk, flash memory, DVD, or similar device.

In the substrate processing apparatus 100 illustrated in FIG. 1, a configuration in which the plasma generation mechanism 30 provided on the lateral side of the processing container 1 generates a plasma of the processing gas and supplies the activated processing gas to the substrates W inside the processing container 1 has been described by way of example, but the present disclosure is not limited thereto. The substrate processing apparatus 100 may also be configured to generate a plasma of the processing gas inside the processing container 1 and supply the activated processing gas to the substrates W inside the processing container 1. In this case, the pair of plasma electrodes 33 are arranged at the opposite sides of the processing container 1 interposed therebetween. Further, the wall surface of the processing container 1 serves as the plasma partition wall defining the plasma generation space.

### [Substrate Processing Process of Substrate Processing Apparatus]

Next, an example of the operation of the substrate processing apparatus 100 will be described. Here, a film forming process for forming a silicon nitride film on the substrate W by an ALD process using a plasma of a silicon-containing gas and a nitrogen-containing gas will be described by way of example.

The film forming process in an example forms a silicon nitride film on the substrate W by repeating a cycle, including a precursor gas supply step, a first purge step, a nitriding step, and a second purge step, a predetermined number of times. Further, in the respective steps, N₂ gas, which is a purge gas, is constantly (continuously) supplied from the gas supply pipe 23 during the film forming process.

The precursor gas supply step is a step of supplying a silicon-containing gas into the processing container 1. In the precursor gas supply step, the control unit 60 opens the on-off valve 21c to supply the silicon-containing gas from the gas source 21a into the processing container 1 through the gas supply pipe 21. Thus, the silicon-containing gas is adsorbed onto the surface of the substrate W.

The first purge step is a step of purging the excess silicon-containing gas and other gases inside the processing container 1. In the first purge step, the control unit 60 closes the on-off valve 21c to stop the supply of the silicon-containing gas. Thus, the purge gas, which is constantly supplied from the gas supply pipe 23, purges the excess silicon-containing gas and other gases inside the processing container 1.

The nitriding step is a step of generating a plasma of a nitrogen-containing gas and supplying active species (e.g., ions and radicals) containing nitrogen (N) into the processing container 1. In the nitriding step, the control unit 60 opens the on-off valve 22c to supply the nitrogen-containing gas from the gas source 22a to the plasma generation space inside the plasma partition wall 32 through the gas supply pipe 22. Further, the control unit 60 controls the radio-frequency power supply 37 to supply radio-frequency power to the plasma electrodes 33, thereby generating a plasma in the plasma generation space inside the plasma partition wall 32. That is, active species containing nitrogen (N) are generated in the plasma generation space and are supplied into the processing container 1 through the opening 31. Thus, the silicon-containing gas adsorbed onto the surface of the substrate W is nitrided, so that a silicon nitride film is formed on the surface of the substrate W.

The second purge step is a step of purging the excess nitrogen-containing gas and other gases inside the processing container 1. In the second purge step, the control unit 60 closes the on-off valve 22c to stop the supply of the nitrogen-containing gas. Further, the control unit 60 controls the radio-frequency power supply 37 to stop the supply of radio-frequency power, consequently stopping plasma generation. Thus, the purge gas, which is constantly supplied from the gas supply pipe 23, purges the excess nitrogen-containing gas and other gases inside the processing container 1.

The above-described precursor gas supply step, first purge step, nitriding step, and second purge step constitute one cycle, and the cycle is repeated a predetermined number of times, whereby a silicon nitride film having a desired film thickness is formed on the substrate W.

The film forming process may also include a modifying step, in order to improve the in-plane film thickness uniformity of the silicon nitride film and the film quality of the silicon nitride film.

The modifying step is a step of generating a plasma of a modifying gas (e.g., hydrogen gas) and supplying active species (e.g., ions and radicals) of the modifying gas into the processing container 1. In the modifying step, the control unit 60 supplies the modifying gas from a modifying gas source (not illustrated) to the plasma generation space inside the plasma partition wall 32 through the gas supply pipe 22. The modifying gas may be, for example, a hydrogen (H₂) gas. Further, the control unit 60 controls the radio-frequency power supply 37 to supply radio-frequency power to the plasma electrodes 33, thereby generating a plasma in the plasma generation space inside the plasma partition wall 32. That is, active species of the modifying gas are generated in the plasma generation space and are supplied into the processing container 1 through the opening 31. Thus, the silicon nitride film formed on the surface of the substrate W is modified.

The modifying step has been described as an example in which the modifying gas activated using a plasma is supplied into the processing container 1, but the present disclosure is not limited thereto. The modifying step may also be configured to supply the modifying gas into the processing container 1.

In this way, the plasma generated in the plasma generation space is used in the nitriding step (e.g., the step of generating a plasma of NH₃ gas) and the modifying step (e.g., the step of generating a plasma of H₂ gas). In an ALD cycle, a cycle including the nitriding step and the modifying step is repeated at high speed. That is, each time a plasma of a different gas is generated, the matching box 35 performs impedance matching. Therefore, it is desirable that the time required to achieve impedance matching in the matching box 35 be short.

In the meantime, in a matching box using a variable capacitor with an adjustable capacitance, the loss of the matching box is small, and even when the matching position (e.g., the capacitance of the variable capacitor that achieves impedance matching) changes, a change in the loss of the matching box remains small. Therefore, in order to compensate only for the loss of the coaxial cable 36 between the radio-frequency power supply 37 and the matching box, a dummy load (not illustrated) is connected instead of the matching box. Then, the control unit 60 sets radio-frequency output power (RF output power) at the radio-frequency power supply 37 to compensate for the loss so that desired radio-frequency power supply (RF supply power) is supplied to the end of the coaxial cable 36. Further, the variable capacitor varies the capacitance thereof via a motor. Therefore, in the matching box using the variable capacitor, the time required to achieve impedance matching is, for example, on the order of seconds.

Further, there are cases where the matching box 35 using a variable inductor capable of adjusting an inductance at high speed is mounted in the substrate processing apparatus 100. In the matching box 35 using the variable inductor, the time required to achieve impedance matching is, for example, on the order of milliseconds.

However, compared to the matching box using the variable capacitor, the matching box 35 using the variable inductor incurs the larger loss of the matching box 35 (e.g., copper loss caused by the resistance of a coil of the variable inductor), and a more significant change in the loss of the matching box 35 caused by the change in the matching position (e.g., in the inductance of the variable inductor that achieves impedance matching). Therefore, in the substrate processing apparatus 100 equipped with the matching box 35 using the variable inductor, it is necessary to consider not only the loss of the coaxial cable 36 between the radio-frequency power supply 37 and the matching box 35 but also the loss of the matching box 35.

Further, the substrate processing apparatus 100 has mechanical differences caused by physical tolerances or installation errors. For example, there are mechanical differences in the distance between the pair of plasma electrodes 33, the distance from one plasma electrode 33 (e.g., the plasma electrode 331 to be described later in FIG. 2) to the grounded heating mechanism 50 (or the grounded shield), the distance from the other plasma electrode 33 (e.g., the plasma electrode 332 to be described later in FIG. 2) to the grounded heating mechanism 50 (or the grounded shield), and the thickness of the plasma partition wall 32 located between the pair of plasma electrodes 33.

These mechanical differences may affect the state of a plasma 39 (see, e.g., FIG. 2 to be described later) generated in the plasma generation space inside the plasma partition wall 32. In other words, these mechanical differences may change the matching position of the matching box 35, causing a change in the loss of the matching box 35, and increasing the mechanical differences in the radio-frequency power (RF supply power) supplied to the plasma electrodes 33 (e.g., plasma electrodes 331 and 332 to be described later in FIG. 2).

### [Matching Box]

Next, the matching box 35 will be further described with reference to FIG. 2. FIG. 2 is a circuit diagram illustrating an example of a circuit that supplies radio-frequency power to the plasma electrodes 33. In FIG. 2, the flow of signals is indicated with dashed arrows.

The plasma electrodes 33 include one plasma electrode 331 and the other plasma electrode 332. The pair of plasma electrodes 331 and 332 are arranged at opposite sides outside the plasma partition wall 32. A plasma generation space in which the plasma 39 is generated is defined inside the plasma partition wall 32.

The radio-frequency power supply 37 includes a power supply 410, a radio-frequency sensor 420, and a power supply control unit 430. Further, the radio-frequency power supply 37 includes a radio-frequency line 451.

The power supply 410 outputs radio-frequency power to the radio-frequency line 451.

The power supply 410 includes, for example, a radio-frequency oscillator and an amplifier. The radio-frequency oscillator generates a sine wave or fundamental wave at a predetermined frequency (e.g., 13.56 MHz). The amplifier amplifies the sine wave or fundamental wave output from the radio-frequency oscillator with a variable controllable gain or amplification factor. The power supply 410 is controlled by the power supply control unit 430.

The radio-frequency (RF) sensor 420 is provided on the radio-frequency line 451 and detects the radio-frequency power output from the radio-frequency power supply 37. Further, the radio-frequency sensor 420 includes a directional coupler on the radio-frequency line 451. The radio-frequency sensor 420 detects power PF1 of a forward wave propagating in the forward direction along the radio-frequency line 451, for example, from the radio-frequency power supply 37 to the matching box 35. Further, the radio-frequency sensor 420 also detects the power RF1 of the reflected wave propagating in the reverse direction along the radio-frequency line 451, for example, from the matching box 35 to the radio-frequency power supply 37. Then, the radio-frequency sensor 420 outputs the detection results to the power supply control unit 430.

The power supply control unit 430 controls the power supply 410 based on a control signal from the control unit 60. Further, the power supply control unit 430 controls the power supply 410 based on the detection results detected by the radio-frequency sensor 420. Further, the power supply control unit 430 outputs the detection results detected by the radio-frequency sensor 420 to the controller 60.

The coaxial cable 36 interconnects the radio-frequency power supply 37 and the matching box 35. Specifically, an inner conductor (e.g., a core wire) of the coaxial cable 36 interconnects the radio-frequency line 451 of the radio-frequency power supply 37 and a radio-frequency feed line 551 of the matching box 35. Further, an outer conductor (e.g., a shield) of the coaxial cable 36 is grounded.

The matching box 35 includes the impedance matching circuit 510, a radio-frequency sensor 520, a voltage sensor 530, and a matching box control unit 540. Further, the matching box 35 includes the radio-frequency feed line 551, a ground line 552, a first load line 553, and a second load line 554.

The radio-frequency feed line 551 is connected to the radio-frequency line 451 of the radio-frequency power supply 37 via the coaxial cable 36. That is, the radio-frequency feed line 551 is a line through which the radio-frequency power is supplied from the radio-frequency power supply 37.

The ground line 552 is a line that is grounded.

The first load line 553 is connected to one plasma electrode 331 via a feed line 341. The second load line 554 is connected to the other plasma electrode 332 via a feed line 342.

The impedance matching circuit 510 includes a plurality of reactance elements 511 to 516. Further, the impedance matching circuit 510 is connected to the radio-frequency feed line 551, the ground line 552, the first load line 553, and the second load line 554.

The reactance element 511 and the variable reactance element 512 are arranged in series between the radio-frequency feed line 551 and the ground line 552. The reactance element (e.g., a first fixed reactance element) 511 is a fixed capacitor (e.g., a condenser) having a capacitance C1. The variable reactance element (e.g., a first variable reactance element or a first variable inductor) 512 is a variable inductor having an adjustable inductance VL1 (Load). The inductance VL1 (Load) of the variable reactance element 512 is controlled by the matching box control unit 540.

The reactance element 513 and the variable reactance element 514 are arranged in series between the first load line 553 and the second load line 554. The reactance element (e.g., a second fixed reactance element) 513 is a fixed capacitor (e.g., a condenser) having a capacitance C2. The variable reactance element (e.g., a second variable reactance element or a second variable inductor) 514 is a variable inductor having an adjustable inductance VL2 (Phase). The inductance VL2 (Phase) of the variable reactance element 512 is controlled by the matching box control unit 540.

The reactance element (e.g., a third fixed reactance element) 515 is located between the radio-frequency feed line 551 and the first load line 553. The reactance element 515 is a fixed inductor (e.g., a coil) having an inductance L1.

The reactance element (e.g., a fourth fixed reactance element) 516 is located between the ground line 552 and the second load line 554. The reactance element 516 is a fixed inductor (e.g., a coil) having an inductance L2.

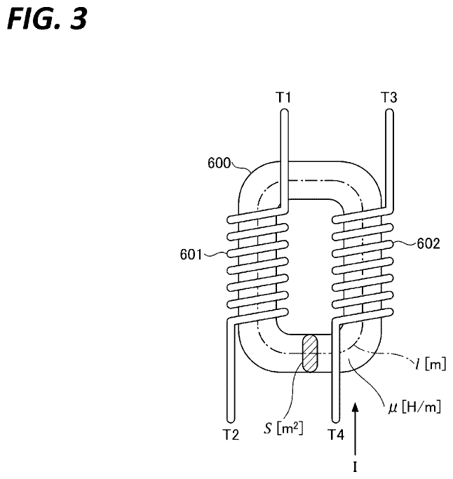

Here, an example configuration of the variable reactance elements (variable inductors) 512 and 514 having an adjustable inductance will be described with reference to FIG. 3. FIG. 3 is a schematic diagram illustrating a configuration of a variable inductor.

The variable inductor includes an annular core 600 and coils 601 and 602 wound around the core 600. The coil 601 corresponds to the variable reactance elements 512 and 514 and is connected to the impedance matching circuit 510. The coil 602 is connected to a power supply (not illustrated), and the current flowing through the coil 602 is controlled by the matching box control unit 540.

Here, the inductance L between terminals T1 and T2 of the coil 601 may be represented by the following equation using the magnetic permeability μ [H/m] of the core 600, the cross-sectional area S [m²] of the core 600, the number of turns N of the coil 601, and the length l [m] of the core 600.

L=μSN²/l[H]

Further, the magnetic permeability u of the core 600 may be varied by varying the direct current I flowing through terminals T3 and T4 of the coil 602.

In other words, the matching box control unit 540 may change the inductance of the coil 601 by controlling the power supply to control the direct current I flowing through the coil 602. In other words, the inductance of the coil 601 may be changed based on the response speed at which the direct current I flowing through the coil 602 is changed. Thus, the inductance of the variable reactance elements 512 and 514 may be adjusted at high speed, thereby shortening the time required to achieve impedance matching by the matching box 35.

Returning to FIG. 2, the radio-frequency (RF) sensor 520 is provided on the radio-frequency feed line 551 and detects the radio-frequency power supplied from the radio-frequency power supply 37. Further, the radio-frequency sensor 520 includes a directional coupler on the radio-frequency feed line 551. The radio-frequency sensor 520 detects power PF2 of a forward wave propagating in the forward direction along the radio-frequency feed line 551, for example, from the radio-frequency power supply 37 to the matching box 35. Further, the radio-frequency sensor 520 also detects power RF2 of the reflected wave propagating in the reverse direction along the radio-frequency feed line 551, for example, from the matching box 35 to the radio-frequency power supply 37. Then, the radio-frequency sensor 520 outputs the detection results to the matching box control unit 540.

The voltage sensor 530 includes a first voltage sensor 531, a second voltage sensor 532, and a third voltage sensor 533.

The first voltage sensor 531 detects the potential difference between the first load line 553 and the ground line 552, and detects the peak-to-peak value of this potential difference. Hereinafter, the peak-to-peak value detected by the first voltage sensor 531 is also referred to as the first peak value Vpp1. Then, the first voltage sensor 531 outputs the detection results to the matching box control unit 540.

The second voltage sensor 532 detects the potential difference between the second load line 554 and the ground line 552, and detects the peak-to-peak value of this potential difference. Hereinafter, the peak-to-peak value detected by the second voltage sensor 532 is also referred to as the second peak value Vpp2. Then, the second voltage sensor 532 outputs the detection results to the matching box control unit 540.

The third voltage sensor 533 detects the potential difference between the first load line 553 and the second load line 554, and detects the peak-to-peak value of this potential difference. Hereinafter, the peak-to-peak value detected by the third voltage sensor 533 is also referred to as the third peak value Vpp3. Then, the third voltage sensor 533 outputs the detection results to the matching box controller 540.

The voltage sensor 530 illustrated in FIG. 2 has been described as including three voltage sensors, namely, the first voltage sensor 531, the second voltage sensor 532, and the third voltage sensor 533, but the present disclosure is not limited thereto. The third voltage sensor 533 may be omitted. In this case, the matching box control unit 540 may calculate the third peak value Vpp3 by calculating the potential difference between the first load line 553 and the second load line 554 from the difference between the potential difference detected by the first voltage sensor 531 and the potential difference detected by the second voltage sensor 532. Likewise, the voltage sensor 530 may be configured to include at least two of the first voltage sensor 531, the second voltage sensor 532, and the third voltage sensor 533.

The matching box control unit 540 controls the variable reactance elements 512 and 514 of the impedance matching circuit 510 based on control signals from the control unit 60. Further, the matching box control unit 540 also controls the variable reactance elements 512 and 514 of the impedance matching circuit 510 based on the detection results detected by the radio-frequency sensor 520 and the voltage sensor 530 (e.g., the first voltage sensor 531, the second voltage sensor 532, and the third voltage sensor 533). Further, the matching box control unit 540 outputs the detection results detected by the radio-frequency sensor 520 and the voltage sensor 530 to the control unit 60.

The feed line 34 includes the feed line 341 and the feed line 342. The feed line 341 interconnects the first load line 553 of the matching box 35 and one plasma electrode 331. The feed line 342 interconnects the second load line 554 of the matching box 35 and the other plasma electrode 332.

With this configuration, the matching box 35 is configured to enable the control of the inductance of the variable reactance elements 512 and 514 by the matching box control unit 540.

Therefore, the matching box control unit 540 controls the inductance of the variable reactance elements 512 and 514 so as to reduce (or bring close to zero) the reflected wave power RF2 based on the detection results of the radio-frequency sensor 520. In other words, the matching box control unit 540 controls the inductance of the variable reactance elements 512 and 514 such that the impedance on the load side including the impedance matching circuit 510 becomes a predetermined impedance.

In addition, the matching box control unit 540 controls the inductance of the variable reactance elements 512 and 514 such that the first peak value Vpp1 (e.g., the peak-to-peak value of one plasma electrode 331) becomes a predetermined set value based on the detection results of the voltage sensor 530.

In addition, the matching box control unit 540 controls the inductance of the variable reactance elements 512 and 514 such that the second peak value Vpp2 (e.g., the peak-to-peak value of the other plasma electrode 332) becomes a predetermined set value based on the detection results of the voltage sensor 530.

In other words, the matching box 35 illustrated in FIG. 2 may achieve impedance matching, and may adjust the peak-to-peak value of one plasma electrode 331 (e.g., the first peak value Vpp1) and the peak-to-peak value of the other plasma electrode 332 (e.g., the second peak value Vpp2). Further, it may also adjust the peak-to-peak value of the voltage between the plasma electrodes 331 and 332 (e.g., the third peak value Vpp3). Thus, it is possible to prevent variations in the state of the plasma 39 caused by mechanical differences in the substrate processing apparatus 100. Further, the matching box 35 may reduce the influence of process results caused by mechanical differences in the substrate processing apparatus 100.

### [Impedance Matching Processing]

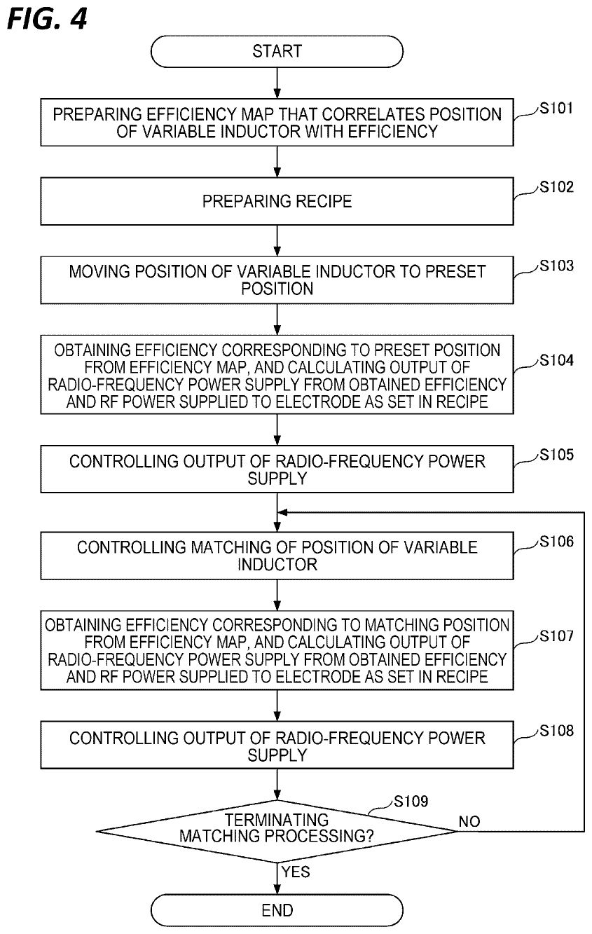

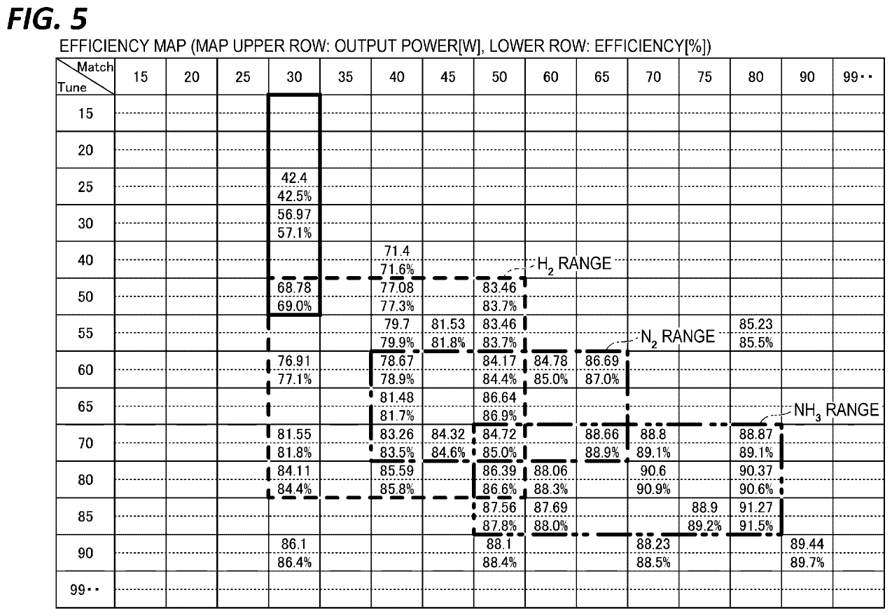

Next, an impedance matching processing will be described with reference to FIGS. 4 and 5. FIG. 4 is an example of a flowchart illustrating an impedance matching processing.

As described above, the matching box 35 using the variable inductors (variable reactance elements 512 and 514) may perform impedance matching at high speed. In the meantime, the loss of the matching box 35 may change depending on a change in the matching position, which may result in a change in the magnitude (e.g., voltage amplitude) of the radio-frequency power supplied to the plasma electrodes 33 (e.g., the plasma electrodes 331 and 332). Therefore, the radio-frequency output power of the radio-frequency power supply 37 is controlled such that the magnitude (e.g., voltage amplitude) of the radio-frequency power supplied to the plasma electrodes 33 (e.g., the plasma electrodes 331 and 332) becomes a predetermined value.

In step S101, an efficiency map is prepared that correlates the position of the variable inductor (e.g., the variable reactance elements 512 and 514) with the efficiency (or loss) of the matching box 35. The efficiency map is stored in the control unit 60.

FIG. 5 is an example of the efficiency map of the matching box 35. The efficiency map is a map that correlates the inductance VL1 of the variable reactance element 512 and the inductance VL2 of the variable reactance element 514 with the efficiency of the matching box 35. In other words, the efficiency map makes it possible to determine the efficiency of the matching 35 based on the inductance VL1 of the variable reactance element 512 and the inductance VL2 of the variable reactance element 514. The efficiency of the matching box 35 is the ratio (%) of the radio-frequency power output from the matching box 35 relative to the radio-frequency power input to the matching box 35.

“Tune” in the vertical direction indicates the variable range of the inductance VL1 (Load) of the variable reactance element 512 as 0% to 100%. “Match” in the horizontal direction indicates the variable range of the inductance VL2 (Phase) of the variable reactance element 514 as 0% to 100%.

The efficiency map may be a map in which “Tune” indicates the variable range of a signal (e.g., direct current I in the example of FIG. 3) used to vary the inductance VL1 (Load) as 0% to 100%, and “Match” indicates the variable range of a signal used to vary the inductance VL1 (Load) (e.g., direct current I in the example of FIG. 3) as 0% to 100%.

Then, the efficiency map indicates the efficiency (or loss) of the matching box 35 corresponding to each Tune and each Match.

For example, when the inductance VL1 (Load) of the variable reactance element 512 is 55% of the variable range (Tune: 55) and the inductance VL2 (Phase) of the variable reactance element 514 is 80% of the variable range (Match: 80), the efficiency of the matching box 35 is stored as 85.5%.

Further, the map also stores the output power from the matching box 35 (in other words, the RF supply power supplied to the plasma electrodes 33) when a predetermined output power (RF output power) is supplied from the radio-frequency power supply 37. In the example of FIG. 5, the upper row indicates the output power (RF output power) from the matching box 35 and the lower row indicates the efficiency of the matching box 35 when 100 W of output power (RF output power) is supplied from the radio-frequency power supply 37 to the matching box 35.

In addition, the impedance matching position range differs depending on each gas used to generate a plasma. For example, in a case of generating an H₂ plasma, impedance matching is achieved at a position within the range of Tune: 50-80% and Match: 30-50%. In a case of generating an N₂ plasma, impedance matching is achieved at a position within the range of Tune: 60-70% and Match: 40-65%. In a case of generating an NH₃ plasma, impedance matching is achieved at a position within the range of Tune: 70-85% and Match: 50-80%.

The efficiency map may be obtained experimentally by supplying a predetermined output power (RF output power) (e.g., 100 W in the example of FIG. 5) from the radio-frequency power supply 37 to the matching box 35 through the coaxial cable 36, connecting a dummy load (not illustrated) instead of the plasma electrodes 33, and detecting the output power from the matching box 35 while changing the position of the variable reactance elements 512 and 514. Further, the efficiency map may be obtained by calculation or simulation based on a circuit configuration of the impedance matching circuit 510.

In step S102, a recipe is prepared. The recipe includes various settings for substrate processing (e.g., including steps for generating a plasma such as nitriding and modifying steps). For example, the recipe includes information such as the type of processing gas used for substrate processing and the magnitude of radio-frequency power supplied to the plasma electrodes 33. The recipe is stored in the control unit 60.

In step S103, the position of the variable inductor is moved to a preset position. Here, the control unit 60 selects the preset position of the variable inductor based on the type of processing gas used for substrate processing as described in the recipe. That is, as illustrated in FIG. 5, a range is set for each processing gas, and the preset position is set within that range. The control unit 60 sets the inductance VL1 of the variable reactance element 512 and the inductance VL2 of the variable reactance element 514 to preset values through the matching box control unit 540.

By setting the inductance VL1 of the variable reactance element 512 and the inductance VL2 of the variable reactance element 514 to preset values based on the recipe, the amount of change required to reach the impedance matching position may be minimized. That is, the time required to achieve impedance matching may be shortened.

In step S104, the efficiency of the matching box 35 corresponding to the preset positions is obtained from the efficiency map, and based on the obtained efficiency and the RF power supplied to the plasma electrodes 33 (e.g., the plasma electrodes 331 and 332) as set in the recipe, the output of the radio-frequency power supply 37 is calculated. The control unit 60 obtains the efficiency of the matching box 35 from the efficiency map and the preset position of the variable inductor (e.g., the preset value of the inductance VL1 and the preset value of the inductance VL2). Further, the control unit 60 calculates the output (RF output power) of the radio-frequency power supply 37 from the RF power (RF supply power) supplied to the plasma electrodes 33 (plasma electrodes 331 and 332) as set in the recipe.

In step S105, the output of the radio-frequency power supply 37 is controlled. Here, the control unit 60 controls the power supply 410 via the power supply control unit 430 such that the output (RF output power) of the radio-frequency power supply 37 becomes the output (RF output power) calculated in step S104.

In step S106, matching control is performed for the position of the variable inductor. Here, the matching box control unit 540 changes the inductance VL1 of the variable reactance element 512 and the inductance VL2 of the variable reactance element 514 to achieve impedance matching. The matching position of the variable inductor (e.g., inductance VL1 and inductance VL2) may be selected based on the higher efficiency of the matching box 35 for the efficient utilization of energy in the plasma. For example, the matching box control unit 540 may actively select the matching position of the variable inductor (e.g., inductance VL1 and inductance VL2) such that the efficiency of the matching box 35 is 80% or higher, as illustrated in the efficiency map of FIG. 5.

In step S107, the efficiency of the matching box 35 corresponding to the matching position is obtained from the efficiency map, and based on the obtained efficiency and the RF power supplied to the plasma electrodes 33 (e.g., the plasma electrodes 331 and 332) as set in the recipe, the output of the radio-frequency power supply 37 is calculated. The control unit 60 obtains the efficiency of the matching box 35 from the efficiency map and the matching position of the variable inductor (e.g., inductance VL1 and inductance VL2). Further, the control unit 60 calculates the output (RF output power) of the radio-frequency power supply 37 from the RF power (RF supply power) supplied to the plasma electrodes 33 (plasma electrodes 331 and 332) as set in the recipe.

In step S108, the output of the radio-frequency power supply 37 is controlled. Here, the control unit 60 controls the power supply 410 via the power supply control unit 430 such that the output (RF output power) of the radio-frequency power supply 37 becomes the output (RF output power) calculated in step S107.

In step S109, it is determined whether the matching processing needs to be terminated. When the matching processing is not terminated (NO in S109), the processing of the control unit 60 returns to step S106. Then, the matching processing of the matching box 35 (S106) and the output control of the radio-frequency power supply 37 (S107 and S108) constitute one cycle, and this cycle is repeated. When the matching processing is terminated (YES in S109), the processing of the control unit 60 is terminated.

The processing of steps S103 to S109 is performed for each plasma generation step (e.g., nitriding and modifying steps) of the recipe. Thus, the time required to achieve impedance matching in an ALD cycle may be reduced, thereby improving the processing performance of the substrate processing apparatus 100.

Further, when the plasma generation steps using the processing gas are repeated in the ALD cycle, the preset positions (preset values) in step S103 may be the impedance matching values from the previous plasma generation step using the processing gas.

According to the above, the matching box 35 may control the radio-frequency output power (RF output power) of the radio-frequency power supply 37 such that the time required to achieve impedance matching is reduced and the radio-frequency power (RF supply power) supplied to the plasma electrodes 33 becomes a predetermined value set in the recipe.

In the above-described example, the control unit 60 that controls the matching box 35 and the radio-frequency power supply 37 performs the control illustrated in FIG. 4, but the present disclosure is not limited thereto. The control illustrated in FIG. 4 may also be executed by exchanging information between the matching box control unit 540 of the matching box 35 and the power supply control unit 430 of the radio-frequency power supply 37.

According to one aspect, it is possible to provide a plasma processing apparatus and a method of controlling the plasma processing apparatus that achieve impedance matching.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be restricting, with the true scope and spirit being indicated by the following claims.

What is claimed is:

1. A plasma processing apparatus comprising:
a radio-frequency power supply;
a pair of plasma electrodes;
a matching box located between the pair of plasma electrodes and the radio-frequency power supply and having an impedance matching circuit including a first variable inductor and a second variable inductor; and
a controller,
wherein the controller has an efficiency map that correlates an inductance of the first variable inductor and an inductance of the second variable inductor with an efficiency of the matching box, and
wherein the controller is configured to execute:
performing impedance matching by varying the inductance of the first variable inductor and the inductance of the second variable inductor;
obtaining the efficiency of the matching box based on the inductance of the first variable inductor and the inductance of the second variable inductor after the impedance matching and the efficiency map, and calculating output power of the radio-frequency power supply based on the obtained efficiency of the matching box and supply power supplied to the plasma electrodes; and
controlling the output power of the radio-frequency power supply based on the calculated output power.

2. The plasma processing apparatus according to claim 1, wherein the controller is further configured to execute:
repeating, as one cycle, the performing the impedance matching, the calculating the output power of the radio-frequency power supply, and the controlling the output power of the radio-frequency power supply.

3. The plasma processing apparatus according to claim 2, wherein the controller is further configured to execute, prior to the repeating:
setting the inductance of the first variable inductor and the inductance of the second variable inductor to preset values;
obtaining the efficiency of the matching box based on the preset values of the inductance of the first variable inductor and the inductance of the second variable inductor and the efficiency map, and calculating the output power of the radio-frequency power supply based on the obtained efficiency of the matching box and the supply power supplied to the plasma electrodes; and
controlling the output power of the radio-frequency power supply based on the calculated output power.

4. The plasma processing apparatus according to claim 1, wherein the matching box includes:
a radio-frequency feed line to which radio-frequency power is supplied from the radio-frequency power supply;
a ground line that is grounded;
a first load line connected to one of the plasma electrodes;
a second load line connected to a remaining one of the plasma electrodes; and
the impedance matching circuit connected to the radio-frequency feed line, the first load line, the second load line, and the ground line, and
wherein the impedance matching circuit includes:
a first fixed reactance element and the first variable inductor connected in series between the radio-frequency power supply line and the ground line;
a second fixed reactance element and the second variable inductor connected in series between the first load line and the second load line;
a third fixed reactance element located between the radio-frequency feed line and the first load line; and
a fourth fixed reactance element located between the second load line and the ground line.

5. The plasma processing apparatus according to claim 1, wherein the performing the impedance matching includes selecting a matching position of the inductance of the first variable inductor and the inductance of the second variable inductor such that the efficiency of the matching box in the efficiency map is 80% or more.

6. A control method comprising:
providing a plasma processing apparatus including:
a radio-frequency power supply;
a pair of plasma electrodes; and a matching box located between the pair of the plasma electrodes and the radio-frequency power supply and having an impedance matching circuit including a first variable inductor and a second variable inductor,
wherein the plasma processing apparatus has an efficiency map that correlates an inductance of the first variable inductor and an inductance of the second variable inductor with an efficiency of the matching box, and
performing impedance matching by varying the inductance of the first variable inductor and the inductance of the second variable inductor;
obtaining the efficiency of the matching box based on the inductance of the first variable inductor and the inductance of the second variable inductor after the impedance matching and the efficiency map, and calculating output power of the radio-frequency power supply based on the obtained efficiency of the matching box and supply power supplied to the plasma electrodes; and
controlling the output power of the radio-frequency power supply based on the calculated output power.
